(19) United States
(12) Patent Application Publication
(10) Pub. No.: US 2025/0216423 A1
(43) Pub. Date: Jul. 3, 2025

(54) TEMPERATURE SENSORS AND ELECTRONIC DEVICES INCLUDING THE TEMPERATURE SENSORS

(71) Applicant: SK hynix Inc., Icheon-si Gyeonggi-do (KR)

(72) Inventors: Seon Hong KIM, Icheon-si Gyeonggi-do (KR); Jin Hoon HYUN, Icheon-si Gyeonggi-do (KR)

(73) Assignee: SK hynix Inc., Icheon-si Gyeonggi-do (KR)

(21) Appl. No.: 18/642,983

(22) Filed: Apr. 23, 2024

(30) Foreign Application Priority Data
Jan. 2, 2024 (KR) 10-2024-0000580

(51) Int. Cl. G01R 19/00; G01K 7/00

(52) U.S. Cl. CPC G01R 19/0038; G01K 7/00

(57) ABSTRACT

A temperature sensor includes a variable voltage selection circuit configured to compare a first variable voltage having a voltage level corresponding to an internal temperature of a first region and a second variable voltage having a voltage level corresponding to an internal temperature of a second region to generate a selected variable voltage, when a selection pulse is generated, and a temperature code generation circuit configured to compare the selected variable voltage to a reference voltage to generate a temperature code whenever a comparison pulse is generated after a temperature code activation signal is activated.

### CROSS-REFERENCE TO RELATED APPLICATIONS

The present application claims priority under 35 U.S.C. 119(a) to Korean Patent Application No. 10-2024-0000580, filed on Jan. 2, 2024, which application is incorporated herein by reference in its entirety.

### BACKGROUND

### 1. Technical Field

Various embodiments of the present disclosure generally relate to temperature sensors, and more particularly, to temperature sensors including electronic devices.

### 2. Related Art

Recently, electronic systems are equipped with sensors that can sense various operating conditions to control the speed and activation of internal operations. The operating conditions sensed by the sensors may include temperature and amount of light. The sensors may include a temperature sensor that generates a temperature code according to temperature and an optical sensor that generates a light sensing code depending on the amount of light.

### SUMMARY

An embodiment of the present disclosure may provide a temperature sensor including a variable voltage selection circuit configured to compare a first variable voltage having a voltage level corresponding to an internal temperature of a first region and a second variable voltage having a voltage level corresponding to an internal temperature of a second region to generate a selected variable voltage, when a selection pulse is generated, and a temperature code generation circuit configured to compare the selected variable voltage to a reference voltage to generate a temperature code whenever a comparison pulse is generated after a temperature code activation signal is activated.

An embodiment of the present disclosure may provide a temperature sensor including a variable voltage selection circuit configured to receive a plurality of variable voltages each set to have a voltage level corresponding to an internal temperature of each of a plurality of regions, and select and output the variable voltage having a highest voltage level among the variable voltages as a selected variable voltage, and a temperature code generation circuit configured to compare the selected variable voltage to a reference voltage to generate a temperature code whenever a comparison pulse is generated after a temperature code activation signal is activated.

An embodiment of the present disclosure may provide an electronic device including a first variable voltage generation circuit located in a first region and configured to generate a first variable voltage having a voltage level corresponding to an internal temperature of the first region, a second variable voltage generation circuit located in a second region and configured to generate a second variable voltage having a voltage level corresponding to an internal temperature of the second region, a variable voltage selection circuit configured to compare the first variable voltage and the second variable voltage to generate a selected variable voltage when a selection pulse is generated, and a temperature code generation circuit configured to compare the selected variable voltage to a reference voltage to generate a temperature code whenever a comparison pulse is generated after a temperature code activation signal is activated.

An embodiment of the present disclosure may provide an electronic device including a variable voltage selection circuit configured to select and output one of a first variable voltage and a second variable voltage measured first as a first selected variable voltage, and select and output one of the first variable voltage and the second variable voltage measured second as a second selected variable voltage, and a temperature code generation circuit configured to compare the first selected variable voltage to a reference voltage to generate a temperature code when the first selected variable voltage is received, and compare the second selected variable voltage to the reference voltage to generate the temperature code when the second selected variable voltage is received.

### BRIEF DESCRIPTION OF THE DRAWINGS

FIG. 1 is a block diagram illustrating a configuration of a temperature sensor according to an embodiment of the present disclosure.

FIG. 2 is a block diagram illustrating a configuration according to an embodiment of a code control circuit included in the temperature sensor shown in FIG. 1.

FIG. 3 is a timing diagram illustrating an operation of the temperature sensor shown in FIGS. 1 and 2 according to an embodiment.

FIG. 4 is a block diagram illustrating a configuration according to an embodiment of an electronic device including the temperature sensor shown in FIG. 1.

FIG. 5 is a block diagram illustrating a configuration according to an embodiment of the electronic device including the temperature sensor shown in FIG. 1.

FIG. 6 is a block diagram illustrating a configuration according an embodiment of the electronic device including the temperature sensor shown in FIG. 1.

FIG. 7 is a block diagram illustrating a configuration of a temperature sensor according to an embodiment of the present disclosure.

FIG. 8 is a block diagram illustrating a configuration according to an embodiment of an electronic device including the temperature sensor shown in FIG. 7.

FIG. 9 is a block diagram illustrating a configuration according to an embodiment of the electronic device including the temperature sensor shown in FIG. 7.

### DETAILED DESCRIPTION

In the following description of embodiments, when a parameter is referred to as being “predetermined,” it may be intended to mean that a value of the parameter is determined in advance when the parameter is used in a process or an algorithm. The value of the parameter may be set when the process or the algorithm starts or may be set during a period in which the process or the algorithm is executed.

It will be understood that although the terms “first,” “second,” “third,” etc. are used herein to describe various elements, these elements should not be limited by these terms. These terms are only used to distinguish one element from another element and are not intended to imply an order or number of elements. Thus, a first element in some embodiments could be termed a second element in other embodiments without departing from the teachings of the present disclosure.

Further, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

A logic “high” level and a logic “low” level may be used to describe logic levels of electric signals. A signal having a logic “high” level may be distinguished from a signal having a logic “low” level. For example, when a signal having a first voltage corresponds to a signal having a logic “high” level, a signal having a second voltage corresponds to a signal having a logic “low” level. In an embodiment, the logic “high” level may be set as a voltage level which is higher than a voltage level of the logic “low” level. Meanwhile, logic levels of signals may be set to be different or opposite according to various embodiments. For example, a certain signal having a logic “high” level in one embodiment may be set to have a logic “low” level in another embodiment.

The term “logic bit set” may mean a combination of logic levels of bits included in a signal. When the logic level of each of the bits included in the signal is changed, the logic bit set of the signal may be set differently. For example, when the signal includes two bits, when the logic level of each of the two bits included in the signal is “logic low level, logic low level”, the logic bit set of the signal may be set as the first logic bit set, and when the logic level of each of the two bits included in the signal is “a logic low level and a logic high level”, the logic bit set of the signal may be set as the second logic bit set.

Various embodiments of the present disclosure will be described hereinafter in more detail with reference to the accompanying drawings. However, the embodiments described herein are for illustrative purposes only and are not intended to limit the scope of the present disclosure.

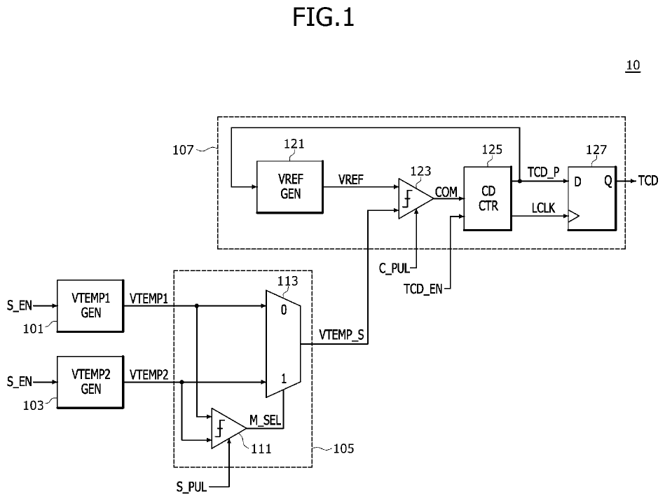

FIG. 1 is a block diagram illustrating a configuration of a temperature sensor 10 according to an embodiment of the present disclosure.

As shown in FIG. 1, the temperature sensor 10 may include a first variable voltage generation circuit (VTEMP1 GEN) 101, a second variable voltage generation circuit (VTEMP2 GEN) 103, a variable voltage selection circuit 105, and a temperature code generation circuit 107.

The first variable voltage generation circuit 101 may generate a first variable voltage VTEMP1, based on a sensing activation signal S_EN. The sensing activation signal S_EN may be activated for a temperature sensing operation in which the temperature sensor 10 senses the internal temperatures of a plurality of regions and generates a temperature code corresponding to the highest internal temperature. The first variable voltage generation circuit 101 may generate the first variable voltage VTEMP1 having a voltage level corresponding to the internal temperature of a first region when the sensing activation signal S_EN is activated. As an example, the first variable voltage generation circuit 101 may generate the first variable voltage VTEMP1 having the voltage level that increases as the internal temperature of the first region increases. The first variable voltage generation circuit 101 may transmit the first variable voltage VTEMP1 to a selection signal generation circuit 111. According to an embodiment, a unit gain buffer (not shown) capable of amplifying the first variable voltage VTEMP1 may be provided between the first variable voltage generation circuit 101 and the selection signal generation circuit 111, so that signal loss that occurs when the first variable voltage VTEMP1 is transmitted can be prevented or mitigated.

The second variable voltage generation circuit 103 may generate a second variable voltage VTEMP2, based on the sensing activation signal S_EN. The second variable voltage generation circuit 103 may generate the second variable voltage VTEMP2 having a voltage level corresponding to the internal temperature of a second region when the sensing activation signal S_EN is activated. As an example, the second variable voltage generation circuit 103 may generate the second variable voltage VTEMP2 having the voltage level that increases as the internal temperature of the second region increases. The second region may be set separately from the first region, and each of the first region and the second region may be set in various ways depending on the embodiment. The second variable voltage generation circuit 103 may transmit the second variable voltage VTEMP2 to the selection signal generation circuit 111. According to an embodiment, a unit gain buffer (not shown) capable of amplifying the second variable voltage VTEMP2 may be provided between the second variable voltage generation circuit 103 and the selection signal generation circuit 111, so that signal loss that occurs when the second variable voltage VTEMP2 is transmitted can be prevented or mitigated.

The variable voltage selection circuit 105 may include the selection signal generation circuit 111 and a selector 113.

The selection signal generation circuit 111 may be electrically connected to the first variable voltage generation circuit 101 and the second variable voltage generation circuit 103 to receive the first variable voltage VTEMP1 from the first variable voltage generation circuit 101 and receive the second variable voltage VTEMP2 from the second variable voltage generation circuit 103. The selection signal generation circuit 111 may generate a selection signal M_SEL, based on a selection pulse S_PUL, the first variable voltage VTEMP1, and the second variable voltage VTEMP2. The selection pulse S_PUL may be generated for a selection operation after the sensing activation signal S_EN is activated. The selection signal generation circuit 111 may compare the first variable voltage VTEMP1 and the second variable voltage VTEMP2 to generate the selection signal M_SEL having a logic level that is set when the selection pulse S_PUL is generated. As an example, the selection signal generation circuit 111 may generate the selection signal M_SEL that is set to have a first logic level for selecting the first variable voltage VTEMP1 when the first variable voltage VTEMP1 has a higher voltage level than the second variable voltage VTEMP2, and generate the selection signal M_SEL that is set to have a second logic level for selecting the second variable voltage VTEMP2 when the second variable voltage VTEMP2 has a higher voltage level than the first variable voltage VTEMP1. As another example, the selection signal generation circuit 111 may be implemented to generate the selection signal M_SEL that is set to have the second logic level for selecting the second variable voltage VTEMP2 when the first variable voltage VTEMP1 has a higher voltage level than the second variable voltage VTEMP2, and may be implemented to generate the selection signal M_SEL that is set to have the first logic level for selecting the first variable voltage VTEMP1 when the second variable voltage VTEMP2 has a higher voltage level than the first variable voltage VTEMP1. The first logic level may be set as a logic “low” level, and the second logic level may be set as a logic “high” level, but this is only an example, and the present disclosure is not limited thereto.

The selector 113 may be electrically connected to the first variable voltage generation circuit 101, the second variable voltage generation circuit 103, and the selection signal generation circuit 111 to receive the first variable voltage VTEMP1 from the first variable voltage generation circuit 101, receive the second variable voltage VTEMP2 from the second variable voltage generation circuit 103, and receive the selection signal M_SEL from the selection signal generation circuit 111. The selector 113 may generate a selected variable voltage VTEMP_S, based on the first variable voltage VTEMP1, the second variable voltage VTEMP2, and the selection signal M_SEL. As an example, the selector 113 may select and output the first variable voltage VTEMP1 as the selected variable voltage VTEMP_S when the first variable voltage VTEMP1 is generated at a higher voltage level than the second variable voltage VTEMP2 and the selection signal M_SEL is set to have the first logic level, and may select and output the second variable voltage VTEMP2 as the selected variable voltage VTEMP_S when the second variable voltage VTEMP2 is generated at a higher voltage level than the first variable voltage VTEMP1 and the selection signal M_SEL is set to have the second logic level. As another example, the selector 113 may be implemented to select and output the second variable voltage VTEMP2 as the selected variable voltage VTEMP_S when the first variable voltage VTEMP1 is generated at a higher voltage level than the second variable voltage VTEMP2 and the selection signal M_SEL is set to have the second logic level, and may be implemented to select and output the first variable voltage VTEMP1 as the selected variable voltage VTEMP_S when the second variable voltage VTEMP2 is generated at a higher voltage level than the first variable voltage VTEMP1 and the selection signal M_SEL is set to have the first logic level.

The variable voltage selection circuit 105 may compare the first variable voltage VTEMP1 and the second variable voltage VTEMP2 when the selection pulse S_PUL is generated to select and output one of the first variable voltage VTEMP1 and the second variable voltage VTEMP2 as the selected variable voltage VTEMP_S. As an example, the variable voltage selection circuit 105 may select and output the first variable voltage VTEMP1 as the selected variable voltage VTEMP_S when the first variable voltage VTEMP1 has a higher voltage level than the second variable voltage VTEMP2, that is, the internal temperature of the first region is higher than the internal temperature of the second region, and may select and output the second variable voltage VTEMP2 as the selected variable voltage VTEMP_S when the second variable voltage VTEMP2 has a higher voltage level than the first variable voltage VTEMP1, that is, the internal temperature of the second region is higher than the internal temperature of the first region. The variable voltage selection circuit 105 may generate the selected variable voltage VTEMP_S having a voltage level corresponding to the selected internal temperature, which is selected to the higher temperature between the internal temperature of the first region and the internal temperature of the second region. For example, the variable voltage selection circuit 105 may be implemented to select and output the second variable voltage VTEMP2 as the selected variable voltage VTEMP_S when the first variable voltage VTEMP1 has a higher voltage level than the second variable voltage VTEMP2, that is, the internal temperature of the first region is higher than the internal temperature of the second region, and may be implemented to select and output the first variable voltage VTEMP1 as the selected variable voltage VTEMP_S when the second variable voltage VTEMP2 has a higher voltage level than the first variable voltage VTEMP1, that is, the internal temperature of the second region is higher than the internal temperature of the first region. The variable voltage selection circuit 105 may generate the selected variable voltage VTEMP_2 having a voltage level corresponding to the selected internal temperature, which is selected to the lower temperature between the internal temperature of the first region and the internal temperature of the second region.

The temperature code generation circuit 107 may include a reference voltage generation circuit (VREF GEN) 121, a comparison circuit 123, a code control circuit (CD CTR) 125, and a temperature code latch 127.

The reference voltage generation circuit 121 may be electrically connected to the code control circuit 125 to receive a pre-temperature code TCD_P from the code control circuit 125. The reference voltage generation circuit 121 may generate a reference voltage VREF, based on the pre-temperature code TCD_P. The reference voltage generation circuit 121 may adjust the voltage level of the reference voltage VREF according to the pre-temperature code TCD_P or adjust the rate of change of the voltage level according to the time change of the reference voltage VREF, but this is only an example and the present disclosure is not limited thereto.

The comparison circuit 123 may be electrically connected to the reference voltage generation circuit 121 and the variable voltage selection circuit 105 to receive the reference voltage VREF from the reference voltage generation circuit 121, and may receive the selected variable voltage VTEMP_S from the variable voltage selection circuit 105. The comparison circuit 123 may generate a comparison signal COM, based on a comparison pulse C_PUL, the reference voltage VREF, and the selected variable voltage VTEMP_S. The comparison pulse C_PUL may be generated multiple times for a comparison operation after a temperature code activation signal TCD_EN is activated. The temperature code activation signal TCD_EN may be activated after the sensing activation signal S_EN is activated and the selection pulse S_PUL is generated. The comparison circuit 123 may compare the selected variable voltage VTEMP_S and the reference voltage VREF to generate the comparison signal COM whenever the comparison pulse C_PUL is generated. The comparison circuit 123 may generate the comparison signal COM that remains in an inactive state whenever the comparison pulse C_PUL is generated during a comparison period in which the selected variable voltage VTEMP_S is generated at a voltage level higher than that of the reference voltage VREF. The comparison circuit 123 may generate the comparison signal COM that is activated when the comparison pulse C_PUL is generated after the selected variable voltage VTEMP_S is generated at a voltage level equal to or lower than that of the reference voltage VREF after the comparison period has elapsed. The logic level at which the comparison signal COM is activated may be set in various ways depending on the embodiment.

The code control circuit 125 may be electrically connected to the comparison circuit 123 to receive the comparison signal COM from the comparison circuit 123. The code control circuit 125 may generate the pre-temperature code TCD_P, based on the comparison signal COM and the temperature code activation signal TCD_EN. The code control circuit 125 may generate the pre-temperature code TCD_P and a latch clock LCLK when the comparison signal COM is activated as a result of the comparison operation, that is, when the selection variable voltage VTEMP_S is generated at a voltage level equal to or lower than that of the reference voltage VREF after the temperature code activation signal TCD_EN is activated.

The temperature code latch 127 may be electrically connected to the code control circuit 125 to receive the pre-temperature code TCD_P and the latch clock LCLK from the code control circuit 125. The temperature code latch 127 may generate a temperature code TCD, based on the pre-temperature code TCD_P and the latch clock LCLK. The temperature code latch 127 may latch the pre-temperature code TCD_P in synchronization with the latch clock LCLK, and may output the pre-temperature code TCD_P as the temperature code TCD.

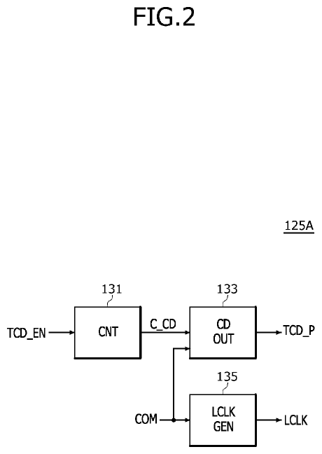

The temperature code generation circuit 107 may compare the selected variable voltage VTEMP_S and the reference voltage VREF to generate the temperature code TCD whenever the comparison pulse C_PUL is generated after the temperature code activation signal TCD_EN is activated. The temperature code generation circuit 107 may perform a counting operation to generate a counting code (for example, C_CD in FIG. 2) during the comparison period in which the selected variable voltage VTEMP_S is generated at a voltage level higher than that of the reference voltage VREF after the temperature code activation signal TCD_EN is activated. The temperature code generation circuit 107 may generate the temperature code TCD, based on the counting code (for example, C_CD in FIG. 2) when the selected variable voltage VTEMP_S is determined to have a voltage level equal to or lower than that of the reference voltage VREF as a result of the comparison operation performed by the comparison pulse C_PUL.

FIG. 2 is a block diagram illustrating a configuration of a code control circuit 125A according to an embodiment of the code control circuit 125 shown in FIG. 1. As shown in FIG. 2, the code control circuit 125A may include a counter (CNT) 131, a code output circuit (CD OUT) 133, and a latch clock generation circuit (LCLK GEN) 135.

The counter 131 may sequentially perform counting operations during the comparison period in which the selected variable voltage VTEMP_S is generated at a voltage level higher than that of the reference voltage VREF after the temperature code activation signal TCD_EN is activated to generate the counting code C_CD. The period of the counting operation performed by the counter 131 may be set to be the same as the period in which the comparison pulse C_PUL is generated, but this is only an example and the present disclosure is not limited thereto.

The code output circuit 133 may be electrically connected to the counter 131 to receive the counting code C_CD from the counter 131. The code output circuit 133 may generate the pre-temperature code TCD_P, based on the comparison signal COM and the counting code C_CD. The code output circuit 133 may output the counting code C_CD as the pre-temperature code TCD_P when the comparison signal COM is activated as a result of the comparison operation after the temperature code activation signal TCD_EN is activated, that is, when the selected variable voltage VTEMP_S is generated at a voltage level equal to or lower than that of the reference voltage VREF.

The latch clock generation circuit 135 may generate the latch clock LCKL, based on the comparison signal COM. The latch clock generation circuit 135 may generate the latch clock LCKL when the comparison signal COM is activated as a result of the comparison operation after the temperature activation signal TCD_EN is activated, that is, when the selected variable voltage VTEMP_S is generated at a voltage level equal to or lower than that of the reference voltage VREF.

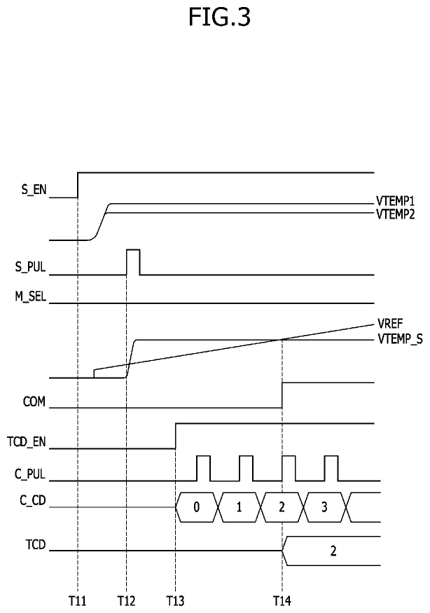

FIG. 3 is a timing diagram illustrating an operation of the temperature sensor 10 shown in FIGS. 1 and 2.

First, referring to FIGS. 1 and 3, when the sensing activation signal S_EN is activated at a logic “high” level for a temperature sensing operation at the time T11, the first variable voltage generation circuit 101 may generate the first variable voltage VTEMP1 having a voltage level corresponding to the internal temperature of the first region, and generate the second variable voltage VTEMP2 having a voltage level corresponding to the internal temperature of the second region.

Next, referring to FIGS. 1 and 3, when the selection pulse S_PUL is generated at the time T12, the variable voltage selection circuit 105 may compare the first variable voltage VTEMP1 and the second variable voltage VTEMP2 to select and output the first variable voltage VTEMP1 as the selected variable voltage VTEMP_S.

Next, referring to FIGS. 2 and 3, after the temperature code activation signal TCD_EN is activated at the time T13, the counter 131 may sequentially perform counting operations to generate the counting code C_CD.

Meanwhile, referring to FIGS. 1 and 3, after the temperature activation signal TCD_EN is activated at the time T13, the comparison circuit 123 may compare the selected variable voltage VTEMP_S and the reference voltage VREF to generate the comparison signal COM whenever the comparison pulse C_PUL is generated. The comparison circuit 123 may generate the comparison signal COM that remains inactive at a logic “low” level whenever the comparison pulse C_PUL is generated during the comparison period T13-T14 in which the selected variable voltage VTEMP_S is generated at a higher voltage level than the reference voltage VREF.

Finally, referring to FIGS. 1 and 3, at the time T14, the selected variable voltage VTEMP_S may be generated at a voltage level equal to or lower than that of the reference voltage VREF when the comparison pulse C_PUL is generated, so that the comparison circuit 123 may generate the comparison signal COM that is activated at a logic “high” level. The code control circuit 125 may generate the pre-temperature code TCD_P and the latch clock LCLK when the comparison signal COM is activated at a logic “high” level. The temperature code latch 127 may latch the pre-temperature code TCD_P in synchronization with the latch clock LCLK, and output the latched pre-temperature code TCD_P as the temperature code TCD.

As described above, the variable voltages VTEMP1 and VTEMP2 corresponding to the temperatures of a plurality of regions may be measured, the variable voltage corresponding to the highest temperature (depending on the embodiment, the lowest temperature) between the measured variable voltages VTEMP1 and VTEMP2 may be selected as the selected variable voltage VTEMP_S, and the temperature code TCD may be adjusted or trimmed to correspond to the selected variable voltage VTEMP_S, thereby measuring the internal temperature of the region with the highest internal temperature among the plurality of regions. In addition, the temperature sensor 10 may repeatedly perform the operation of adjusting or trimming the temperature code depending on the selected variable voltage VTEMP_S each time the temperature sensor 10 measures the variable voltages VTEMP1 and VTEMP2 corresponding to the temperatures of the plurality of regions, thereby accurately generating the temperature code corresponding to the highest internal temperature among the internal temperatures of the plurality of regions.

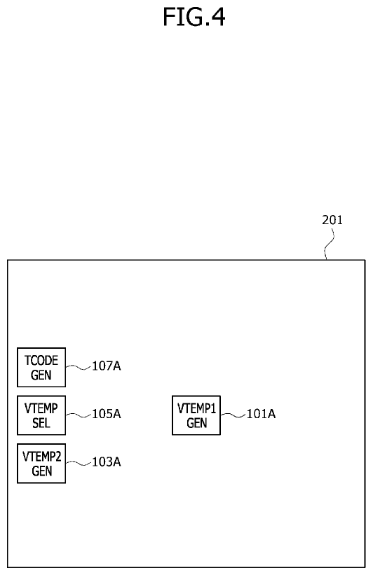

FIG. 4 is a block diagram illustrating a configuration according to an embodiment of an electronic device 201 including the temperature sensor 10 shown in FIG. 1.

As shown in FIG. 4, the electronic device 201 may include a first variable voltage generation circuit (VTEMP1 GEN) 101A, a second variable voltage generation circuit (VTEMP2 GEN) 103A, a variable voltage selection circuit (VTEMP SEL) 105A, and a temperature code generation circuit (TCODE GEN) 107A. The first variable voltage generation circuit 101A may be located in a central region of the electronic device 201, and may generate the first variable voltage VTEMP1 corresponding to the internal temperature of the central region of the electronic device 201. The second variable voltage generation circuit 103A may be located in a left region of the electronic device 201, and may generate the second variable voltage VTEMP2 corresponding to the internal temperature of the left region of the electronic device 201. The variable voltage selection circuit 105A and the temperature code generation circuit 107A may be located adjacent to the second variable voltage generation circuit 103A in the left region of the electronic device 201. The first variable voltage generation circuit 101A, the second variable voltage generation circuit 103A, the variable voltage selection circuit 105A, and the temperature code generation circuit 107A may be implemented to be the same as the first variable voltage generation circuit 101, the second variable voltage generation circuit 103, the variable voltage selection circuit 105, and the temperature code generation circuit 107, respectively, so detailed descriptions of each configuration are omitted. Each of the left region of the electronic device 201 and the central region of the electronic device 201 may be implemented as one of the region where various logic circuits (not shown) for controlling internal operations are formed, the region where internal clocks are generated, and the region where circuits for controlling signal transmission to external devices (not shown) are formed, but this is only an example, and the present disclosure is not limited thereto. The left region may be located in a first direction in the central region, and the first direction may be variously set according to embodiments.

In an embodiment, the electronic device 201 may be implemented to include the first variable voltage generation circuit 101A in the central region, include the second variable voltage generation circuit 103A in the left region, and include the variable voltage selection circuit 105A and temperature code generation circuit 107A that receive the first variable voltage VTEMP1 and the second variable voltage VTEMP2 to generate the temperature code TCD, thereby reducing the layout area of the temperature sensor provided therein.

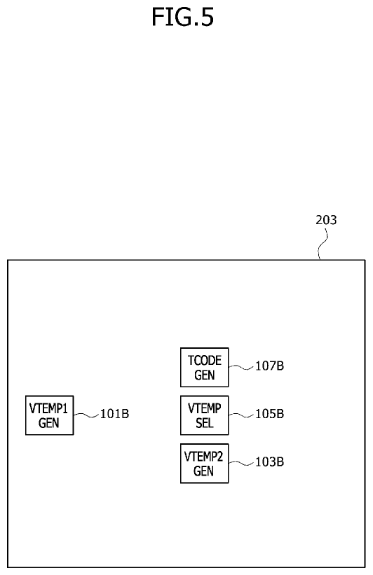

FIG. 5 is a block diagram illustrating a configuration according to an embodiment of an electronic device 203 including the temperature sensor 10 shown in FIG. 1.

As shown in FIG. 5, the electronic device 203 may include a first variable voltage generation circuit (VTEMP1 GEN) 101B, a second variable voltage generation circuit (VTEMP2 GEN) 103B, a variable voltage selection circuit (VTEMP SEL) 105B, and a temperature code generation circuit (TCODE GEN) 107B. The first variable voltage generation circuit 101B may be located in a left region of the electronic device 203, and may generate the first variable voltage VTEMP1 corresponding to the internal temperature of the left region of the electronic device 203. The second variable voltage generation circuit 103B may be located in a central region of the electronic device 203, and may generate the second variable voltage VTEMP2 corresponding to the internal temperature of the central region of the electronic device 203. The variable voltage selection circuit 105B and the temperature code generation circuit 107B may be located adjacent to the second variable voltage generation circuit 103B in the central region of the electronic device 203. The first variable voltage generation circuit 101B, the second variable voltage generation circuit 103B, the variable voltage selection circuit 105B, and the temperature code generation circuit 107B may be implemented to be the same as the first variable voltage generation circuit 101, the second variable voltage generation circuit 103, the variable voltage selection circuit 105, and the temperature code generation circuit 107, respectively, so detailed descriptions of each configuration are omitted. Each of the left region of the electronic device 203 and the central region of the electronic device 203 may be implemented as one of the region where various logic circuits (not shown) for controlling internal operations are formed, the region where internal clocks are generated, and the region where circuits for controlling signal transmission to external devices (not shown) are formed, but this is only an example, and the present disclosure is not limited thereto.

In an embodiment, the electronic device 203 may be implemented to include the first variable voltage generation circuit 101B in the left region, include the second variable voltage generation circuit 103B in the central region, and include the variable voltage selection circuit 105B and temperature code generation circuit 107B that receive the first variable voltage VTEMP1 and the second variable voltage VTEMP2 to generate the temperature code TCD, thereby reducing the layout area of the temperature sensor provided therein.

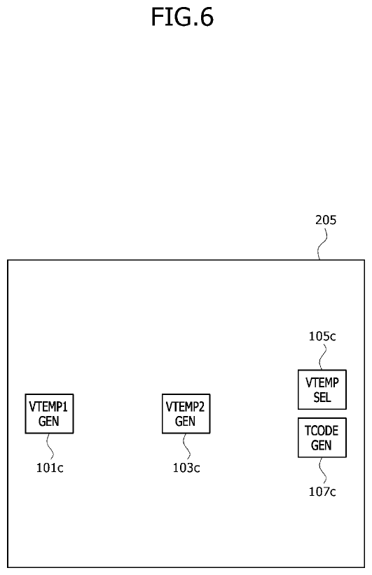

FIG. 6 is a block diagram illustrating a configuration according to an embodiment of an electronic device 205 including the temperature sensor 10 shown in FIG. 1.

As shown in FIG. 6, the electronic device 205 may include a first variable voltage generation circuit (VTEMP1 GEN) 101C, a second variable voltage generation circuit (VTEMP2 GEN) 103C, a variable voltage selection circuit (VTEMP SEL) 105C, and a temperature code generation circuit (TCODE GEN) 107C. The first variable voltage generation circuit 101C may be located in a left region of the electronic device 205, and may generate the first variable voltage VTEMP1 corresponding to the internal temperature of the left region of the electronic device 205. The second variable voltage generation circuit 103C may be located in a central region of the electronic device 205, and may generate the second variable voltage VTEMP2 corresponding to the internal temperature of the central region of the electronic device 205. The variable voltage selection circuit 105C and the temperature code generation circuit 107C may be located in a right region of the electronic device 205. The first variable voltage generation circuit 101C, the second variable voltage generation circuit 103C, the variable voltage selection circuit 105C, and the temperature code generation circuit 107C may be implemented to be the same as the first variable voltage generation circuit 101, the second variable voltage generation circuit 103, the variable voltage selection circuit 105, and the temperature code generation circuit 107, respectively, so detailed descriptions of each configuration are omitted. Each of the left region of the electronic device 205 and the central region of the electronic device 205 may be implemented as one of the region where various logic circuits (not shown) for controlling internal operations are formed, the region where internal clocks are generated, and the region where circuits for controlling signal transmission to external devices (not shown) are formed, but this is only an example, and the present disclosure is not limited thereto. The right region may be located in a second direction in the central region, and the second direction may be set in the opposite direction to the first direction.

In an embodiment, the electronic device 205 may be implemented to include the first variable voltage generation circuit 101C in the left region, include the second variable voltage generation circuit 103C in the central region, and include the variable voltage selection circuit 105C and temperature code generation circuit 107C that receive the first variable voltage VTEMP1 and the second variable voltage VTEMP2 to generate the temperature code TCD, thereby reducing the layout area of the temperature sensor provided therein.

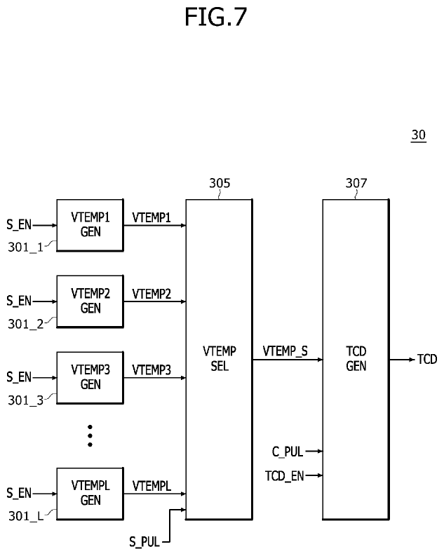

FIG. 7 is a block diagram illustrating a configuration of a temperature sensor 30 according to an embodiment of the present disclosure.

As shown in FIG. 7, the temperature sensor 30 may include first to “L”^{th} variable voltage generation circuits (VTEMP1 GEN-VTEMPL GEN) 301_1-301_L, a variable voltage selection circuit 305, and a temperature code generation circuit 307.

The first variable voltage generation circuit 301_1 may generate a first variable voltage VTEMP1, based on a sensing activation signal S_EN. The first variable voltage generation circuit 301_1 may generate the first variable voltage VTEMP1 having a voltage level corresponding to the internal temperature of a first region when the sensing activation signal S_EN is activated. As an example, the first variable voltage generation circuit 301_1 may generate the first variable voltage VTEMP1 having a voltage level that increases as the internal temperature of the first region increases. The first variable voltage generation circuit 301_1 may transmit the first variable voltage VTEMP1 to the selection signal generation circuit 305. According to embodiments, a unit gain buffer (not shown) capable of amplifying the first variable voltage VTEMP1 may be provided between the first variable voltage generation circuit 301_1 and the selection signal generation circuit 305, so that signal loss that occurs when the first variable voltage VTEMP1 is transmitted can be prevented or mitigated.

The second variable voltage generation circuit 301_2 may generate the second variable voltage VTEMP2, based on the sensing activation signal S_EN. The second variable voltage generation circuit 301_2 may generate the second variable voltage VTEMP2 having a voltage level corresponding to the internal temperature of the second region when the sensing activation signal S_EN is activated. As an example, the second variable voltage generation circuit 301_2 may generate the second variable voltage VTEMP2 having a voltage level that increases as the internal temperature of the second region increases. The second variable voltage generation circuit 301_2 may transmit the second variable voltage VTEMP2 to the selection signal generation circuit 305. According to embodiments, a unit gain buffer (not shown) capable of amplifying the second variable voltage VTEMP2 may be provided between the second variable voltage generation circuit 301_2 and the selection signal generation circuit 305, so that signal loss that occurs when the second variable voltage VTEMP2 is transmitted can be prevented or mitigated.

The third variable voltage generation circuit 301_3 may generate a third variable voltage VTEMP3, based on the sensing activation signal S_EN. The third variable voltage generation circuit 301_3 may generate the third variable voltage VTEMP3 having a voltage level corresponding to the internal temperature of a third region when the sensing activation signal S_EN is activated. As an example, the third variable voltage generation circuit 301_3 may generate the third variable voltage VTEMP3 having a voltage level that increases as the internal temperature of the third region increases. The third variable voltage generation circuit 301_3 may transmit the third variable voltage VTEMP3 to the selection signal generation circuit 305. According to embodiments, a unit gain buffer (not shown) capable of amplifying the third variable voltage VTEMP3 may be provided between the third variable voltage generation circuit 301_3 and the selection signal generation circuit 305, so that signal loss that occurs when the third variable voltage VTEMP3 is transmitted can be prevented or mitigated.

The “L”^{th} variable voltage generation circuit 301_L may generate an “L”^{th} variable voltage VTEMPL, based on the sensing activation signal S_EN. The “L”^{th} variable voltage generation circuit 301_L may generate the “L”^{th} variable voltage VTEMPL having a voltage level corresponding to the internal temperature of an “L”^{th} region when the sensing activation signal S_EN is activated. As an example, the “L”^{th} variable voltage generation circuit 301_L may generate the “L”^{th} variable voltage VTEMPL having a voltage level that increases as the internal temperature of the “L”^{th} region increases. The “L”^{th} variable voltage generation circuit 301_L may transmit the “L”^{th} variable voltage VTEMPL to the selection signal generation circuit 305. According to embodiments, a unit gain buffer (not shown) capable of amplifying the “L”^{th} variable voltage VTEMPL may be provided between the “L”^{th} variable voltage generation circuit 301_L and the selection signal generation circuit 305, so that signal loss that occurs when the “L”^{th} variable voltage VTEMPL is transmitted can be prevented or mitigated.

The variable voltage selection circuit 305 may compare the first to “L”^{th} variable voltages VTEMP1-VTEMPL to select and output one of the first to “L”^{th} variable voltages VTEMP1-VTEMPL as a selected variable voltage VTEMP_S when the selection pulse S_PUL is generated. As an example, when the second variable voltage VTEMP2 has the highest voltage level among the first to “L”^{th} variable voltages VTEMP1-VTEMPL, that is, when the internal temperature of the second region among the first to “L”^{th} regions is the highest, the variable voltage selection circuit 305 may select and output the second variable voltage VTEMP2 as the selected variable voltage VTEMP_S. As another example, when the third variable voltage VTEMP3 has the lowest voltage level among the first to “L”^{th} variable voltages VTEMP1-VTEMPL, that is, when the internal temperature of the third region among the first to “L”^{th} regions is the lowest, the variable voltage selection circuit 305 may be implemented to select and output the third variable voltage VTEMP3 as the selected variable voltage VTEMP_S.

The temperature code generation circuit 307 may compare the selected variable voltage VTEMP_S and the reference voltage VREF to generate the temperature code TCD whenever the comparison pulse C_PUL is generated after the temperature code activation signal TCD_EN is activated. The temperature code generation circuit 307 may perform a counting operation during a comparison period in which the selected variable voltage VTEMP_S is generated at a higher voltage level than the reference voltage VREF after the temperature code activation signal TCD_EN is activated. The temperature code generation circuit 307 may generate the temperature code TCD when the selected variable voltage VTEMP_S is determined to have a lower voltage level than the reference voltage VREF as a result of the comparison operation performed by the comparison pulse C_PUL.

The temperature sensor 30 shown in FIG. 7 may be apart from the temperature sensor 10 shown in FIG. 1 including the first variable voltage generation circuit 101 and the second variable voltage generation circuit 103 generating the first variable voltage VTEMP1 and the second variable voltage VTEMP2, respectively, in that the temperature sensor 30 includes the first to “L”^{th} variable voltage generation circuits 301_1-301_L that measure the internal temperatures on the “L” regions to generate the first to “L”^{th} variable voltages VTEMP1-VTEMPL, respectively.

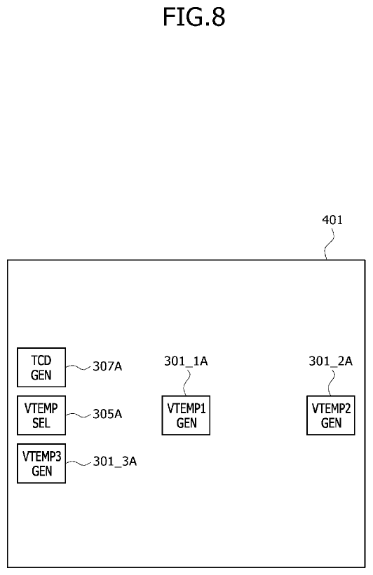

FIG. 8 is a block diagram illustrating a configuration according to an embodiment of an electronic device 401 including the temperature sensor 30 shown in FIG. 7.

As shown in FIG. 8, the electronic device 401 may include a first variable voltage generation circuit (VTEMP1 GEN) 301_1A, a second variable voltage generation circuit (VTEMP2 GEN) 301_2A, a third variable voltage generation circuit (VTEMP3 GEN) 301_3A, a variable voltage selection circuit (VTEMP SEL) 305A, and a temperature code generation circuit (TCODE GEN) 307A. The first variable voltage generation circuit 301_1A may be located in a central region of the electronic device 401, and may generate the first variable voltage VTEMP1 corresponding to the internal temperature of the central region of the electronic device 401. The second variable voltage generation circuit 301_2A may be located in a right region of the electronic device 401, and may generate the second variable voltage VTEMP2 corresponding to the internal temperature of the right region of the electronic device 401. The third variable voltage generation circuit 301_3A may be located in a left region of the electronic device 401, and may generate the third variable voltage VTEMP3 corresponding to the internal temperature of the left region of the electronic device 401. Each of the variable voltage selection circuit 305A and the temperature code generation circuit 307A may be located adjacent to the third variable voltage generation circuit 301_3A in the left region of the electronic device 401. The first variable voltage generation circuit 301_1A, the second variable voltage generation circuit 301_2A, the third variable voltage generation circuit 301_3A, the variable voltage selection circuit 305A, and the temperature code generation circuit 307A may correspond to the first to “L”^{th} variable voltage generation circuits 301_1-301_L, the variable voltage selection circuit 305, and the temperature code generation circuit 307 included in the temperature sensor 30 shown in FIG. 7, respectively. Therefore, detailed descriptions of each component are omitted. Each of the left region of the electronic device 401, the right region of the electronic device 401, and the central region of the electronic device 401 may be implemented as one of the region where various logic circuits (not shown) for controlling internal operations are formed, the region where internal clocks are generated, and the region where circuits for controlling signal transmission to external devices (not shown) are formed, but this is only an example and the present disclosure is not limited thereto.

In an embodiment, the electronic device 401 may be implemented to include the first variable voltage generation circuit 301_1A in the central region, include the second variable voltage generation circuit 301_2A in the right region, include the third variable voltage generation circuit 301_3A in the left region, and include the variable voltage selection circuit 305A and the temperature code generation circuit 307A that receive the first variable voltage VTEMP1, the second variable voltage VTEMP2, and the third variable voltage VTEMP3 to generate the temperature code TCD, thereby reducing the layout area of the temperature sensor provided therein.

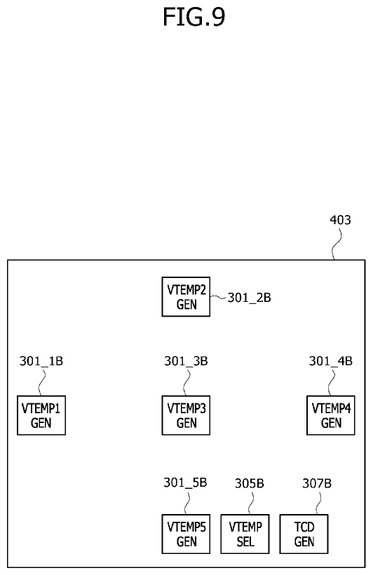

FIG. 9 is a block diagram illustrating a configuration according to an embodiment of an electronic device 403 including the temperature sensor 30 shown in FIG. 7.

As shown in FIG. 9, the electronic device 403 may include a first variable voltage generation circuit (VTEMP1 GEN) 301_1B, a second variable voltage generation circuit (VTEMP2 GEN) 301_2B, a third variable voltage generation circuit (VTEMP3 GEN) 301_3B, a fourth variable voltage generation circuit (VTEMP4 GEN) 301_4B, a fifth variable voltage generation circuit (VTEMP5 GEN) 301_5B, a variable voltage selection circuit (VTEMP SEL) 305B, and a temperature code generation circuit (TCODE GEN) 307B. The first variable voltage generation circuit 301_1B may be located in a left region of the electronic device 403, and may generate the first variable voltage VTEMP1 corresponding to the internal temperature of the left region of the electronic device 403. The second variable voltage generation circuit 301_2B may be located in an upper region of the electronic device 403, and may generate the second variable voltage VTEMP2 corresponding to the internal temperature of the upper region of the electronic device 403. The third variable voltage generation circuit 301_3B may be located in a central region of the electronic device 403, and may generate the third variable voltage VTEMP3 corresponding to the internal temperature of the central region of the electronic device 403. The fourth variable voltage generation circuit 301_4B may be located in a right region of the electronic device 403, and may generate a fourth variable voltage VTEMP4 corresponding to the internal temperature of the right region of the electronic device 403. The fifth variable voltage generation circuit 301_5B may be located in a lower region of the electronic device 403, and may generate a fifth variable voltage VTEMP5 corresponding to the internal temperature of the lower region of the electronic device 403. The variable voltage selection circuit 305B and the temperature code generation circuit 307B may be located adjacent to the fifth variable voltage generation circuit 301_5B in the lower region of the electronic device 403. The first variable voltage generation circuit 301_1B, the second variable voltage generation circuit 301_2B, the third variable voltage generation circuit 301_3B, the fourth variable voltage generation circuit 301_4B, the fifth variable voltage generation circuit 301_5B, the variable voltage selection circuit 305B, and the temperature code generation circuit 307B may correspond to the first to “L”^{th} variable voltage generation circuits 301_1-301_L, the variable voltage selection circuit 305, and the temperature code generation circuit 307 included in the temperature sensor 30 shown in FIG. 7, respectively. Therefore, detailed descriptions of each component are omitted. Each of the upper region of the electronic device 403, the lower region of the electronic device 403, the left region of the electronic device 403, the right region of the electronic device 403, and the central region of the electronic device 403 may be implemented as one of the region where various logic circuits (not shown) for controlling internal operations are formed, the region where internal clocks are generated, and the region where circuits for controlling signal transmission to external devices (not shown) are formed, but this is only an example and the present disclosure is not limited thereto. The upper region may be located in a third direction in the central region, the lower region may be located in a fourth direction in the central region, the third direction may be set in a direction opposite to the fourth direction, and each of the third direction and the fourth direction may be set to be orthogonal to the first direction and the second direction.

In an embodiment, the electronic device 403 may be implemented to include the first variable voltage generation circuit 301_1B in the left region, include the second variable voltage generation circuit 301_2B in the upper region, include the third variable voltage generation circuit 301_3B in the central region, include the fourth variable voltage generation circuit 301_4B in the right region, include the fifth variable voltage generation circuit 301_5B in the lower region, and include the variable voltage selection circuit 305B and temperature code generation circuit 307B that receive the first variable voltage VTEMP1, the second variable voltage VTEMP2, the third variable voltage VTEMP3, the fourth variable voltage VTEMP4, and the fifth variable voltage VTEMP5 to generate the temperature code TCD, thereby reducing the layout area of the temperature sensor provided therein.

Concepts have been disclosed in conjunction with some embodiments as described above. Those skilled in the art will appreciate that various modifications, additions, and substitutions are possible, without departing from the scope and spirit of the present disclosure. Accordingly, the embodiments disclosed in the present specification should be considered from not a restrictive standpoint but rather from an illustrative standpoint. The scope of the concepts is not limited to the above descriptions but defined by the accompanying claims, and all of distinctive features in the equivalent scope should be construed as being included in the concepts.

What is claimed is:

1. A temperature sensor comprising:
a variable voltage selection circuit configured to compare a first variable voltage having a voltage level corresponding to an internal temperature of a first region and a second variable voltage having a voltage level corresponding to an internal temperature of a second region to generate a selected variable voltage, when a selection pulse is generated; and
a temperature code generation circuit configured to compare the selected variable voltage to a reference voltage to generate a temperature code whenever a comparison pulse is generated after a temperature code activation signal is activated.

2. The temperature sensor of claim 1, wherein the variable voltage selection circuit is configured to receive the selection pulse generated after the sensing activation signal is activated for a temperature sensing operation.

3. The temperature sensor of claim 1, wherein the variable voltage selection circuit is configured to select and output a variable voltage having a higher voltage level between the first variable voltage and the second variable voltage as the selected variable voltage.

4. The temperature sensor of claim 1, wherein the variable voltage selection circuit is configured to select and output a variable voltage having a lower voltage level between the first variable voltage and the second variable voltage as the selected variable voltage.

5. The temperature sensor of claim 1, wherein the variable voltage selection circuit comprises:
a selection signal generation circuit configured to compare the first variable voltage and the second variable voltage to generate a selection signal when the selection pulse is generated; and
a selector configured to select and output one of the first variable voltage and the second variable voltage, based on the selection signal.

6. The temperature sensor of claim 5, wherein the selection signal generation circuit is configured to:
generate the selection signal and set the selection signal to have a first logic level when the first variable voltage has a higher voltage level than the second variable voltage, and
generate the selection signal and set the selection signal to have a second logic level when the second variable voltage has a higher voltage level than the first variable voltage.

7. The temperature sensor of claim 1, wherein the temperature code generation circuit is configured to receive the comparison pulse that is generated a plurality of times for a comparison operation after the selection pulse is generated and the temperature code activation signal is activated.

8. The temperature sensor of claim 1, wherein the temperature code generation circuit is configured to:
perform a counting operation to generate a counting code when the comparison pulse is generated during a comparison period in which the selected variable voltage is generated at a voltage level higher than that of the reference voltage, and
generate the temperature code, based on the counting code when the selected variable voltage is generated at a voltage level equal to or lower than that of the reference voltage and the comparison pulse is generated.

9. The temperature sensor of claim 1, wherein the temperature code generation circuit comprises:
a comparison circuit configured to compare the selected variable voltage and the reference voltage to generate a comparison signal whenever the comparison pulse is generated;
a code control circuit configured to generate a pre-temperature code and a latch clock, based on the comparison signal after a temperature code activation signal is activated; and
a temperature code latch configured to latch the pre-temperature code in synchronization with the latch clock and output the pre-temperature code latched as the temperature code.

10. The temperature sensor of claim 9, wherein the code control circuit comprises:
a counter configured to perform a counting operation to generate a counting code after the temperature code activation signal is activated;
a code output circuit configured to output the counting code as the pre-temperature code when the comparison signal is activated; and
a latch clock generation circuit configured to generate the latch clock when the comparison signal is activated.

11. A temperature sensor comprising:
a variable voltage selection circuit configured to receive a plurality of variable voltages each set to have a voltage level corresponding to an internal temperature of each of a plurality of regions, and select and output the variable voltage having a highest voltage level among the variable voltages as a selected variable voltage; and
a temperature code generation circuit configured to compare the selected variable voltage to a reference voltage to generate a temperature code whenever a comparison pulse is generated after a temperature code activation signal is activated.

12. The temperature sensor of claim 11,
wherein the plurality of regions include first, second, and third regions,
wherein the plurality of variable voltages include first, second, and third variable voltages, and
wherein the variable voltage selection circuit is configured to:
receive the first variable voltage having a voltage level corresponding to the internal temperature of the first region,
receive the second variable voltage having a voltage level corresponding to the internal temperature of the second region, and
receive the third variable voltage having a voltage level corresponding to the internal temperature of the third region.

13. The temperature sensor of claim 12, wherein the variable voltage selection circuit is configured to:
select and output the first variable voltage as the selected variable voltage when the internal temperature of the first region among the first, second, and third regions is the highest,
select and output the second variable voltage as the selected variable voltage when the internal temperature of the second region among the first, second, and third regions is the highest, and
select and output the third variable voltage as the selected variable voltage when the internal temperature of the third region among the first, second, and third regions is the highest.

14. The temperature sensor of claim 11, wherein the temperature code generation circuit is configured to receive the comparison pulse generated a plurality of times for a comparison operation after the selection pulse is generated and the temperature code activation signal is activated.

15. The temperature sensor of claim 11, wherein the temperature code generation circuit is configured to:
perform a counting operation to generate a counting code when the comparison pulse is generated during a comparison period in which the selected variable voltage is generated at a voltage level higher than that of the reference voltage, and
generate the temperature code, based on the counting code when the selected variable voltage is generated at a voltage level equal to or lower than that of the reference voltage and the comparison pulse is generated.

16. An electronic device comprising:
a first variable voltage generation circuit located in a first region and configured to generate a first variable voltage having a voltage level corresponding to an internal temperature of the first region;
a second variable voltage generation circuit located in a second region different from the first region and configured to generate a second variable voltage having a voltage level corresponding to an internal temperature of the second region;
a variable voltage selection circuit configured to compare the first variable voltage and the second variable voltage to generate a selected variable voltage when a selection pulse is generated; and
a temperature code generation circuit configured to compare the selected variable voltage to a reference voltage to generate a temperature code whenever a comparison pulse is generated after a temperature code activation signal is activated.

17. The electronic device of claim 16, wherein each of the variable voltage selection circuit and the temperature code generation circuit is located in one of the first region and the second region.

18. The electronic device of claim 16, wherein each of the variable voltage selection circuit and the temperature code generation circuit is located in a third region located separately from the first region and the second region.

19. An electronic device comprising:
a variable voltage selection circuit configured to select and output one of a first variable voltage and a second variable voltage measured first as a first selected variable voltage, and select and output one of the first variable voltage and the second variable voltage measured second as a second selected variable voltage; and
a temperature code generation circuit configured to compare the first selected variable voltage to a reference voltage to generate a temperature code when the first selected variable voltage is received, and compare the second selected variable voltage to the reference voltage to generate the temperature code when the second selected variable voltage is received.

20. The electronic device of claim 19,
wherein the first variable voltage has a voltage level corresponding to an internal temperature of a first region, and
wherein the second variable voltage has a voltage level corresponding to an internal temperature of a second region.
